(19) United States
(12) Patent Application Publication
(10) Pub. No.: US 2014/0290993 A1
(43) Pub. Date: Oct. 2, 2014

(54) MULTILAYER CERAMIC CAPACITOR, MANUFACTURING METHOD THEREOF, AND CIRCUIT BOARD FOR MOUNTING ELECTRONIC COMPONENT

(71) Applicant: SAMSUNG ELECTRO-MECHANICS CO., LTD., Suwon (KR)

(72) Inventors: Jong Hoon KIM, Suwon (KR); Byung Soo KIM, Suwon (KR); Hyung Joon KIM, Suwon (KR)

(21) Appl. No.: 13/924,506

(22) Filed: Jun. 21, 2013

(30) Foreign Application Priority Data
Apr. 2, 2013 (KR) 10-2013-0035793

(51) Int. Cl. H01G 4/12; H05K 1/18

(52) U.S. Cl. CPC H01G 4/12; H05K 1/181
USPC 174/258; 361/301.4; 29/25.03

(57) ABSTRACT

There is provided a multilayer ceramic capacitor including: a ceramic body including a plurality of dielectric layers laminated therein; an active part including a plurality of first and second internal electrodes alternately exposed to both end surfaces of the ceramic body, having the dielectric layer interposed therebetween, and forming capacitance; an upper cover layer formed on the active part and including an upper marking electrode therein; and first and second external electrodes formed on the end surfaces of the ceramic body and electrically connected to the first and second internal electrodes, respectively, wherein when a thickness of the dielectric layer is d and a distance between a first internal electrode formed in the uppermost portion of the active part and the upper marking electrode is A1, 2d≦A1 is satisfied.

### CROSS-REFERENCE TO RELATED APPLICATIONS

This application claims the priority of Korean Patent Application No. 10-2013-0035793 filed on Apr. 2, 2013, in the Korean Intellectual Property Office, the disclosure of which is incorporated herein by reference.

### BACKGROUND OF THE INVENTION

1. Field of the Invention

The present invention relates to a multilayer ceramic capacitor allowing for internal electrodes to be effectively protected and improving cutting precision, a manufacturing method thereof, and a circuit board for mounting an electronic component.

2. Description of the Related Art

In general, electronic components using a ceramic material, such as a capacitor, an inductor, a piezoelectric element, a varistor, or a thermistor, and the like, include a ceramic body formed of a ceramic material, internal electrodes formed within the ceramic body, and external electrodes mounted on surfaces of the ceramic body to be connected to the internal electrodes.

Among ceramic electronic components, a multilayer ceramic capacitor includes a plurality of stacked dielectric layers, internal electrodes disposed to face each other, having the dielectric layer interposed therebetween, and external electrodes electrically connected to the internal electrodes.

The multilayer ceramic capacitor has been widely used as a component in computers, mobile communications devices such as personal digital assistants (PDAs), mobile phones, and the like, due to inherent advantages thereof such as a small size, high capacitance, ease of mounting, and the like.

Recently, as electronic products have been miniaturized and have had multi-functionalization implemented therein, chip components have also tended to be miniaturized and to have multi-functionalization implemented therein. Therefore, a small sized multilayer ceramic capacitor having high capacitance has been demanded.

Further, in order to improve product reliability, capacitance distribution should be improved within multilayer ceramic capacitors. To this end, a multilayer ceramic capacitor capable of improving cutting precision during a process of cutting a ceramic lamination body before sintering and effectively protecting internal electrodes thereof has been demanded.

### RELATED ART DOCUMENT

(Patent Document 1) Japanese Patent Laid-Open Publication No. 2005-020673

### SUMMARY OF THE INVENTION

An aspect of the present invention provides a multilayer ceramic capacitor allowing for internal electrodes to be effectively protected while having improved cutting precision, a manufacturing method thereof, and a circuit board for mounting an electronic component.

According to an aspect of the present invention, there is provided a multilayer ceramic capacitor including: a ceramic body including a plurality of dielectric layers laminated therein; an active part including a plurality of first and second internal electrodes alternately exposed to both end surfaces of the ceramic body, having the dielectric layer interposed therebetween, and forming capacitance; an upper cover layer formed on the active part and including an upper marking electrode therein; and first and second external electrodes formed on the end surfaces of the ceramic body and electrically connected to the first and second internal electrodes, respectively, wherein when a thickness of the dielectric layer is d and a distance between a first internal electrode formed in the uppermost portion of the active part and the upper marking electrode is A1, 2d≦A1 is satisfied.

The upper marking electrode may not be exposed to a surface of the upper cover layer.

When a distance between an upper surface of the ceramic body and the upper marking electrode is B1, 1 μm≦B1≦7 μm may be satisfied.

The upper marking electrode and the first and second internal electrodes may be formed of the same material.

The upper marking electrode may be exposed to one of the end surfaces of the ceramic body.

The upper marking electrode may not be exposed to the end surfaces of the ceramic body.

The multilayer ceramic capacitor may further include a lower cover layer below the active part.

The lower cover layer may include a lower marking electrode therein, and when the thickness of the dielectric layer is d and a distance between a second internal electrode formed in the lowermost portion of the active part and the lower marking electrode is A2, 2d≦A2 may be satisfied.

The lower marking electrode may not be exposed to a surface of the lower cover layer.

When a distance between a lower surface of the ceramic body and the lower marking electrode is B2, 1 μm≦B2≦7 μm may be satisfied.

According to another aspect of the present invention, there is provided a manufacturing method of a multilayer ceramic capacitor, the manufacturing method including: preparing a plurality of ceramic green sheets; forming an internal electrode pattern or a marking electrode pattern on each of the ceramic green sheets; laminating the green sheets to prepare a ceramic green sheet lamination body including the internal electrode pattern and the marking electrode pattern therein; recognizing the marking electrode pattern to cut the ceramic green sheet lamination body; and sintering the ceramic green sheet lamination body to manufacture a ceramic body including dielectric layers, an active part including a plurality of first and second internal electrodes alternately exposed to both end surfaces of the ceramic body, having the dielectric layer interposed therebetween to thereby form capacitance, and an upper cover layer formed on the active part and including an upper marking electrode disposed therein.

When a thickness of the dielectric layer is d and a distance between a first internal electrode formed in the uppermost portion of the active part and the upper marking electrode is A1, 2d≦A1 may be satisfied.

The upper marking electrode may not be exposed to a surface of the upper cover layer.

When a distance between an upper surface of the ceramic body and the upper marking electrode is B1, 1 μm≦B1≦7 μm may be satisfied.

The upper marking electrode and the first and second internal electrodes may be formed of the same material.

The upper marking electrode may be exposed to one of the end surfaces of the ceramic body.

The upper marking electrode may not be exposed to the end surfaces of the ceramic body.

The ceramic body may further include a lower cover layer below the active part.

The lower cover layer may include a lower marking electrode therein, and when a thickness of the dielectric layer is d and a distance between a second internal electrode formed in the lowermost portion of the active part and the lower marking electrode is A2, 2d≦A2 may be satisfied.

The lower marking electrode may not be exposed to a surface of the lower cover layer.

When a distance between a lower surface of the ceramic body and the lower marking electrode is B2, 1 μm≦B2≦7 μm may be satisfied.

According to another aspect of the present invention, there is provided a circuit board for mounting an electronic component including: a printed circuit board having first and second electrode pads formed thereon; and a multilayer ceramic capacitor installed on the printed circuit board, wherein the multilayer ceramic capacitor includes: a ceramic body including a plurality of dielectric layers laminated therein; an active part including a plurality of first and second internal electrodes alternately exposed to both end surfaces of the ceramic body, having the dielectric layer interposed therebetween, and forming capacitance; an upper cover layer formed on the active part and including an upper marking electrode therein; and first and second external electrodes formed to cover the end surfaces of the ceramic body; and when a thickness of the dielectric layer is d and a distance between a first internal electrode formed in the uppermost portion of the active part and the upper marking electrode is A1, 2d≦A1 is satisfied.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view showing a multilayer ceramic capacitor according to an embodiment of the present invention;

FIG. 2 is a cross-sectional view taken along line A-A′ of FIG. 1;

FIG. 3 is a cross-sectional view showing a multilayer ceramic capacitor according to another embodiment of the present invention; and

FIG. 4 is a perspective view showing a circuit board for mounting an electronic component according to another embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

Multilayer Ceramic Capacitor

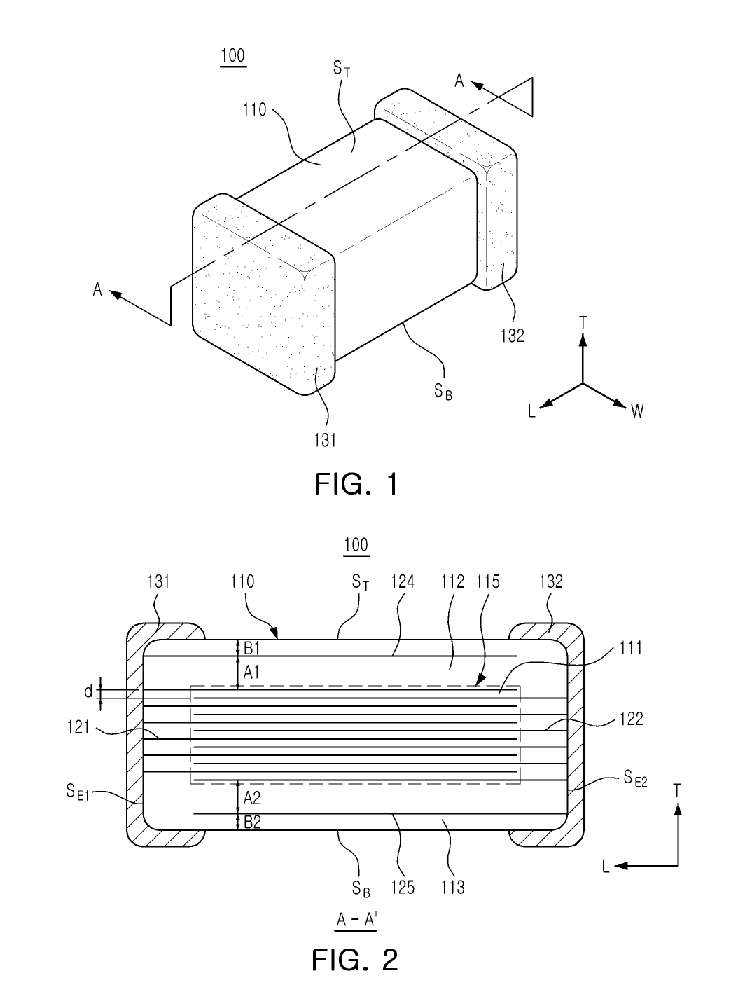

FIG. 1 is a schematic perspective view showing a multilayer ceramic capacitor according to an embodiment of the present invention.

FIG. 2 is a cross-sectional view taken along line A-A′ of FIG. 1.

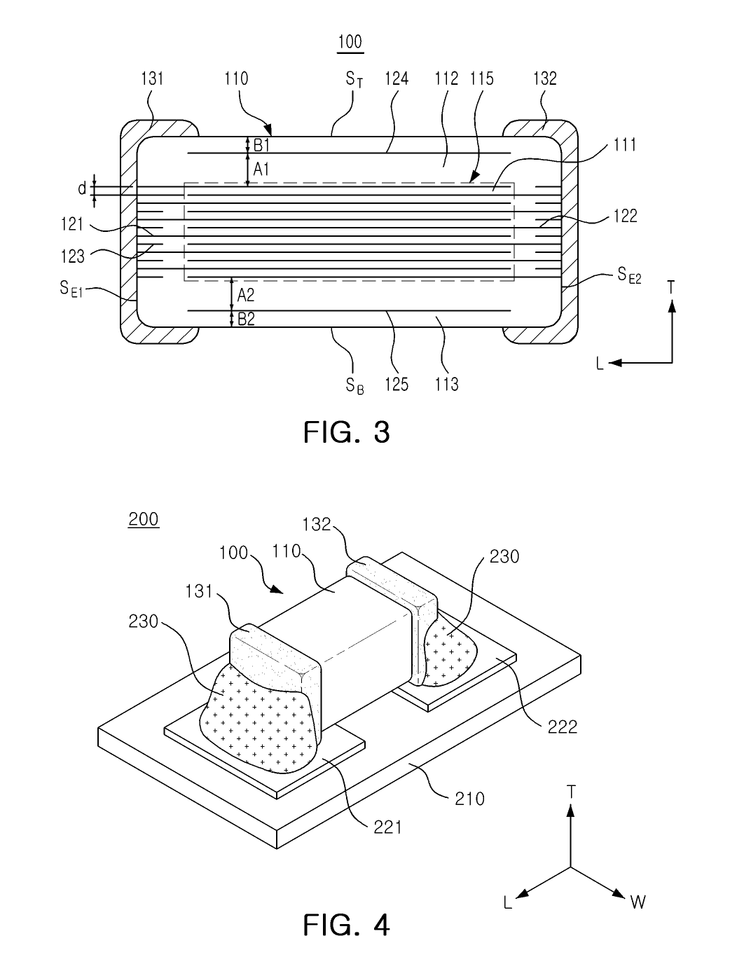

FIG. 3 is a cross-sectional view showing a multilayer ceramic capacitor according to another embodiment of the present invention.

Referring to FIG. 1, a multilayer ceramic capacitor 100 according to an embodiment of the present invention may include a ceramic body 110; and first and second external electrodes 131 and 132.

According to the embodiment of the invention, a T-direction, which is a thickness direction of the ceramic body, refers to a direction in which internal electrodes are laminated, having a dielectric layer interposed therebetween, an L-direction refers to a length direction of the ceramic body, and a W-direction refers to a width direction of the ceramic body.

In the embodiment of the invention, a shape of the ceramic body 110 is not particularly limited, but may be substantially hexahedral. A difference in thickness is generated according to the sintering shrinkage of ceramic powder at the time of sintering a chip and the presence or absence of an internal electrode pattern, and corners of the ceramic body are polished, such that the ceramic body 110 does not have a perfect hexahedral shape but may have a shape substantially close to a hexahedral shape.

Outer surfaces of the ceramic body opposite to each other in the thickness direction may be upper and lower surfaces S_{T} and S_{B} of the ceramic body, two surfaces of the ceramic body opposite to each other in the length direction may be first and second end surfaces S_{E1} and S_{E2}, and two surfaces of the ceramic body opposite to in the width direction may be first and second side surfaces.

Referring to FIG. 2, the ceramic body 110 may include a plurality of dielectric layers 111, an active part 115 including a plurality of first and second internal electrodes 121 and 122 alternately exposed to both end surfaces of the ceramic body 110, having the dielectric layer 111 interposed therebetween, and upper and lower cover layers 112 and 113 formed on upper and lower portions of the active part 115, respectively.

According to the embodiment of the invention, the plurality of dielectric layers 111 configuring the ceramic body 110 may be in a sintered state, and adjacent dielectric layers may be integrated with each other such that a boundary therebetween may not be clearly discernible.

The first and second internal electrodes 121 and 122, a pair of electrodes having opposite polarities, may be formed by printing a conductive paste containing a conductive metal on the respective dielectric layers 111 at a predetermined thickness to be alternately exposed to both end surfaces of the ceramic body and be electrically insulated from each other by the dielectric layer 111 disposed therebetween.

That is, portions of the first and second internal electrodes 121 and 122 alternately exposed to the both end surfaces of the ceramic body 110 may be electrically connected to the first and second external electrodes 131 and 132, respectively.

Therefore, when voltage is applied to the first and second external electrodes 131 and 132, electric charges are accumulated between the first and second internal electrodes 121 and 122 facing each other. In this case, capacitance of the multilayer ceramic capacitor 100 may be in proportion to an area of an overlap region between the first and second internal electrodes 121 and 122.

Further, the conductive metal contained in the first and second internal electrodes 121 and 122 may be nickel (Ni), copper (Cu), palladium (Pd), or an alloy thereof, but the invention is not limited thereto.

Further, the dielectric layer 111 may contain ceramic powder having high permittivity, for example, barium titanate (BaTiO₃) based powder or strontium titanate (SrTiO₃) based powder, or the like, but the invention is not limited thereto.

The upper and lower cover layers 112 and 113 may have the same material and configuration as those of the dielectric layers 111 except that internal electrodes are not included therein. The upper and lower cover layers may be formed by laminating a single dielectric layer 111 or two or more dielectric layers 111 on upper and lower surfaces of the active part 115 in a vertical direction, respectively, and generally serve to prevent the first and second internal electrodes 121 and 122 from being damaged by physical or chemical stress.

The first external electrode 131 may be electrically connected to the first internal electrode 121, and the second external electrode 132 may be electrically connected to the second internal electrode 122.

Further, the upper cover layer 112 may include an upper marking electrode 124 therein, and the lower cover layer 113 may include a lower marking electrode 125 therein.

In the case in which the marking electrode is formed in the upper or lower cover layer, damage to the internal electrodes may be more efficiently prevented.

Since the upper and lower marking electrodes 124 and 125 are disposed outwardly of the first and second internal electrodes 121 and 122 within the ceramic body 110, the upper and lower marking electrodes 124 and 125 may respond to a physical or chemical influence prior to the internal electrodes to thereby protect the internal electrodes.

Particularly, in the case in which the cover layer does not include the marking electrode, an internal electrode positioned at the outermost position of the active part may be damaged to thereby decrease capacitance, but in the case in which the cover layer includes the marking electrode, the internal electrode included in the active part may not be damaged, such that a decrease in capacitance may be significantly reduced.

Further, in the case in which the upper and lower marking electrodes 124 and 125 are formed of the same material as that of the first and second internal electrodes 121 and 122, an influence of external stimulus on the internal electrodes may be further reduced.

Therefore, a multilayer ceramic capacitor of which a difference between initially designed capacitance and actual capacitance is small may be manufactured, and accordingly, capacitance distribution may be improved.

In addition, as shown in FIG. 2, when a thickness of the dielectric layer 111 is d, a distance between a first internal electrode formed in the uppermost portion of the active part 115 and the upper marking electrode 124 is A1, and a distance between a second internal electrode formed in the lowermost portion of the active part 115 and the lower marking electrode 125 is A2, the upper and lower marking electrodes are disposed so as to satisfy the following Equations, respectively: 2d≦A1 and 2d≦A2, such that the upper and lower marking electrodes may be distinguished from the internal electrodes included in the active part.

Further, in the case in which the marking electrodes are exposed to the surfaces of the ceramic body, the first and second external electrodes may be electrically connected to each other through the marking electrodes to generate short-circuits. Therefore, the upper and lower marking electrodes may be formed so as not to be exposed to the surfaces S_{T} and S_{B} of the ceramic body, that is, surfaces of the cover layers.

In addition, when a distance between the upper surface S_{T} of the ceramic body and the upper marking electrode 124 is B1, and a distance between the lower surface S_{B} of the ceramic body and the lower marking electrode 125 is B2, the upper and lower marking electrodes may be disposed so as to satisfy the following Equations, respectively: 1 μm≦B1≦7 μm and 1 μm≦B2≦7 μm.

As described above, since the first and second external electrodes are electrically connected to each other to generate the short-circuits, the upper and lower marking electrodes may be disposed to be spaced apart from the upper or lower surface of the ceramic body by 1 μm or more.

In addition, the upper and lower marking electrodes according to the embodiment of the invention may serve as cutting marks for recognizing a cutting position during a manufacturing process of a multilayer ceramic electronic component. To this end, the upper and lower marking electrodes may be disposed within 7 μm or less from the upper and lower surfaces of the ceramic body, respectively. In the case in which the marking electrodes are disposed 7 μm or more from the upper and lower surfaces of the ceramic body, respectively, it may be difficult to recognize the marking electrodes through the outer surfaces of the ceramic body, such that it may be difficult for the marking electrodes to serve as the cutting marks.

The marking electrodes 124 and 125 may be formed in at least one of the upper and lower cover layers 112 and 113 of the ceramic body.

That is, the marking electrode may be formed in the upper or lower cover layer or formed in both of the upper and lower cover layers.

In addition, the upper and lower marking electrodes 124 and 125 may be exposed to respective end surfaces of the ceramic body as shown in FIG. 2 or may not be exposed to both end surfaces of the ceramic body as shown in FIG. 3.

In the case in which the upper and lower marking electrodes 124 and 125 are exposed to respective end surfaces of the ceramic body, they may be formed to have the same shape as that of the first or second internal electrode 121 or 122.

Particularly, the upper marking electrode may be disposed to have the same shape as that of the first internal electrode, and the lower marking electrode may be disposed to have the same shape as that of the second internal electrode. In other words, the upper and lower marking electrodes may be disposed to have the same pattern as that of respective internal electrodes closest thereto, such that the marking electrodes do not contribute to forming capacitance.

That is, since the upper marking electrode and an internal electrode (first internal electrode) closest thereto are connected to the same external electrode (first external electrode), and the lower marking electrode and an internal electrode (second internal electrode) closest thereto are connected to the same external electrode (second external electrode), the marking electrodes and the respective internal electrodes closest thereto have the same polarity, such that the marking electrodes do not contribute to forming the capacitance. Even in the case that the marking electrodes are damaged by the external stimulus, the capacitance of the multilayer ceramic capacitor may not be changed, such that the capacitance distribution may be more effectively improved.

A description of the case in which the upper and lower marking electrodes function as the cutting marks will be provided in detail in a manufacturing method of a multilayer ceramic capacitor.

Method of Manufacturing Multilayer Ceramic Capacitor

According to another embodiment of the invention, there is provided a method of manufacturing a multilayer ceramic capacitor.

The method of manufacturing a multilayer ceramic capacitor according to the embodiment of the invention may include: preparing a plurality of ceramic green sheets; forming an internal electrode pattern or a marking electrode pattern on each of the ceramic green sheets; laminating the green sheets to prepare a ceramic green sheet lamination body including the internal electrode pattern and the marking electrode pattern therein; recognizing the marking electrode pattern to cut the ceramic green sheet lamination body; and sintering the ceramic green sheet lamination body to manufacture a ceramic body including dielectric layers, an active part including a plurality of first and second internal electrodes alternately exposed to both end surfaces of the ceramic body, having the dielectric layer interposed therebetween to form capacitance, and an upper cover layer formed on the active part and including an upper marking electrode disposed therein. In addition, a lower cover layer including a lower marking electrode may further be formed below the active part.

Hereinafter, the method of manufacturing a multilayer ceramic capacitor according to the embodiment of the invention will be described, but the invention is not limited thereto.

In addition, among descriptions of the method of manufacturing a multilayer ceramic capacitor according to the present embodiment, a description overlapped with that of the above-described multilayer ceramic capacitor 100 will be omitted.

In the method of manufacturing a multilayer ceramic capacitor according to the embodiment of the invention, slurry containing powder such as barium titanate (BaTiO₃) powder, or the like, may be applied to carrier films and dried to prepare a plurality of ceramic green sheets, thereby forming dielectric layers and cover layers.

The ceramic green sheets may be manufactured by mixing the ceramic powder, a binder, and a solvent to prepare the slurry and manufacturing the prepared slurry as sheets having a thickness of several μm using a doctor blade method.

Next, a conductive paste for internal electrodes containing conductive powder may be prepared.

After the internal electrode patterns or the marking electrode patterns are formed by applying the conductive paste for internal electrodes on the green sheets using a screen printing method, a plurality of green sheets on which the internal electrode patterns are printed may be laminated. Then, a plurality of green sheets on which the internal electrode patterns are not printed may be laminated on upper and lower surfaces of the lamination body and the green sheets on which the marking electrode patterns are printed may be laminated therein, thereby preparing the ceramic green sheet lamination body.

The marking electrode pattern needs to be formed within a predetermined thickness from the upper or lower surface of the ceramic green sheet lamination body to be recognized by the naked eyes or an imaging camera through the upper or lower surface of the ceramic green sheet lamination body.

More specifically, the marking electrode pattern may be disposed within 7 μm from the upper or lower surface of the ceramic green sheet lamination body.

Next, the marking electrode pattern may be recognized through the upper or lower surface of the ceramic green sheet lamination body as a mark for determining a cutting position, and the ceramic green sheet lamination body may be cut and sintered, thereby forming a ceramic body.

As shown in FIG. 2, in the case in which the internal electrode pattern included in the finally manufactured multilayer ceramic capacitor does not include an additional dummy electrode, the upper or lower marking electrode pattern may be formed to have the same shape as that of the first or second internal electrode pattern. That is, the upper marking electrode pattern may be formed to have the same shape as that of the first internal electrode pattern, and the lower marking electrode pattern may be formed to have the same shape as that of the second internal electrode pattern.

Alternatively, both of the upper and lower marking electrode patterns may be formed to have the same shape as that of the first internal electrode pattern.

In this case, the cutting position may be a central portion of the marking electrode pattern and a central portion of a region of the ceramic green sheet lamination body in which the marking electrode pattern is not formed, in a length direction of the ceramic green sheet lamination body, and the marking electrode pattern may be exposed to at least one end surface of the cut ceramic green sheet lamination body.

According to another embodiment of the invention, as shown in FIG. 3, in the case in which the internal electrode pattern included in the finally manufactured multilayer ceramic capacitor includes a dummy electrode 123 that does not contribute to forming capacitance, the upper or lower marking electrode pattern may be formed to have the same shape as that of the first or second internal electrode pattern except for the dummy electrode or formed so as not to be exposed to the end surface of the finally manufactured multilayer ceramic capacitor.

In the case in which the marking electrode pattern is formed to have the same shape as that of the first or second internal electrode pattern, the cutting position may be a central portion of the marking electrode pattern and a central portion of a region of the ceramic green sheet lamination body in which the marking electrode pattern is not formed, in the length direction of the ceramic green sheet lamination body, similarly to the above-mentioned embodiment, and the marking electrode pattern may be exposed to at least one end surface of the cut ceramic green sheet lamination body.

Further, in the case in which the marking electrode pattern is formed so as not to be exposed to the end surface of the finally manufactured multilayer ceramic capacitor, the marking electrode may be disposed so that a central portion of a region of the ceramic green sheet lamination body in which the marking electrode pattern is not formed may be recognized as the cutting position.

The ceramic body may include the internal electrodes 121 and 122, the dielectric layers 111, and the cover layers 112 and 113. Here, the dielectric layer is formed by sintering the green sheet on which the internal electrode pattern is printed, and the cover layer is formed by sintering the green sheet on which the internal electrode pattern is not printed and the green sheet on which the marking electrode pattern is formed.

The external electrodes 131 and 132 may be formed on the outer surfaces of the ceramic body 110 to be electrically connected to the first and second internal electrodes 121 and 122, respectively. The external electrodes may be formed by sintering a paste containing a conductive metal and glass.

The conductive metal is not particularly limited, but may be, for example, at least one selected from a group consisting of copper (Cu), silver (Ag), nickel (Ni), and an alloy thereof. As described above, the external electrodes may preferably include copper (Cu) as the conductive metal.

The glass is not particularly limited, but may have the same composition as that of glass used to manufacture external electrodes of a general multilayer ceramic capacitor.

Circuit Board for Mounting Electronic Component

FIG. 4 is a perspective view showing a circuit board for mounting an electronic component according to another embodiment of the present invention.

Referring to FIG. 4, a circuit board 200 for mounting an electronic component according to the embodiment of the invention may include a printed circuit board 210 having first and second electrode pads 221 and 222 formed thereon; and the multilayer ceramic capacitor 100 installed on the printed circuit board 210.

In this case, the multilayer ceramic capacitor 100 may be electrically connected to the printed circuit board 210 by solder 230 in a state in which the first and second external electrodes 131 and 132 are positioned to contact the first and second electrode pads 221 and 222.

A description of contents of the circuit board for mounting the multilayer ceramic capacitor overlapped with those of the above-mentioned multilayer ceramic capacitor 100 will be omitted.

As set forth above, according to the embodiments of the invention, the multilayer ceramic capacitor capable of effectively protecting the internal electrodes and improving the cutting precision of the ceramic green sheet lamination body during the manufacturing process, the manufacturing method thereof, and the circuit board for mounting an electronic component may be provided.

While the present invention has been shown and described in connection with the embodiments, it will be apparent to those skilled in the art that modifications and variations can be made without departing from the spirit and scope of the invention as defined by the appended claims.

What is claimed is:

1. A multilayer ceramic capacitor comprising:
a ceramic body including a plurality of dielectric layers laminated therein;
an active part including a plurality of first and second internal electrodes alternately exposed to both end surfaces of the ceramic body, having the dielectric layer interposed therebetween, and forming capacitance;
an upper cover layer formed on the active part and including an upper marking electrode therein; and
first and second external electrodes formed on the end surfaces of the ceramic body and electrically connected to the first and second internal electrodes, respectively,
wherein when a thickness of the dielectric layer is d and a distance between a first internal electrode formed in the uppermost portion of the active part and the upper marking electrode is A1, 2d≦A1 is satisfied.

2. The multilayer ceramic capacitor of claim 1, wherein the upper marking electrode is not exposed to a surface of the upper cover layer.

3. The multilayer ceramic capacitor of claim 1, wherein when a distance between an upper surface of the ceramic body and the upper marking electrode is B1, 1 μm≦B1≦7 μm is satisfied.

4. The multilayer ceramic capacitor of claim 1, wherein the upper marking electrode and the first and second internal electrodes are formed of the same material.

5. The multilayer ceramic capacitor of claim 1, wherein the upper marking electrode is exposed to one of the end surfaces of the ceramic body.

6. The multilayer ceramic capacitor of claim 1, wherein the upper marking electrode is not exposed to the end surfaces of the ceramic body.

7. The multilayer ceramic capacitor of claim 1, further comprising a lower cover layer below the active part.

8. The multilayer ceramic capacitor of claim 7, wherein the lower cover layer includes a lower marking electrode therein, and
when the thickness of the dielectric layer is d and a distance between a second internal electrode formed in the lowermost portion of the active part and the lower marking electrode is A2, 2d≦A2 is satisfied.

9. The multilayer ceramic capacitor of claim 8, wherein the lower marking electrode is not exposed to a surface of the lower cover layer.

10. The multilayer ceramic capacitor of claim 8, wherein when a distance between a lower surface of the ceramic body and the lower marking electrode is B2, 1 μm≦B2≦7 μm is satisfied.

11. A method of manufacturing a multilayer ceramic capacitor, the method comprising:
preparing a plurality of ceramic green sheets;
forming an internal electrode pattern or a marking electrode pattern on each of the ceramic green sheets;
laminating the green sheets to prepare a ceramic green sheet lamination body including the internal electrode pattern and the marking electrode pattern therein;
recognizing the marking electrode pattern to cut the ceramic green sheet lamination body; and
sintering the ceramic green sheet lamination body to manufacture a ceramic body including dielectric layers, an active part including a plurality of first and second internal electrodes alternately exposed to both end surfaces of the ceramic body, having the dielectric layer interposed therebetween to thereby form capacitance, and an upper cover layer formed on the active part and including an upper marking electrode disposed therein.

12. The method of claim 11, wherein when a thickness of the dielectric layer is d and a distance between a first internal electrode formed in the uppermost portion of the active part and the upper marking electrode is A1, 2d≦A1 is satisfied.

13. The method of claim 11, wherein the upper marking electrode is not exposed to a surface of the upper cover layer.

14. The method of claim 11, wherein when a distance between an upper surface of the ceramic body and the upper marking electrode is B1, 1 μm≦B1≦7 μm is satisfied.

15. The method of claim 11, wherein the upper marking electrode and the first and second internal electrodes are formed of the same material.

16. The method of claim 11, wherein the upper marking electrode is exposed to one of the end surfaces of the ceramic body.

17. The method of claim 11, wherein the upper marking electrode is not exposed to the end surfaces of the ceramic body.

18. The method of claim 11, wherein the ceramic body further includes a lower cover layer below the active part.

19. The method of claim 18, wherein the lower cover layer includes a lower marking electrode therein, and
when a thickness of the dielectric layer is d and a distance between a second internal electrode formed in the lowermost portion of the active part and the lower marking electrode is A2, 2d≦A2 is satisfied.

20. The method of claim 19, wherein the lower marking electrode is not exposed to a surface of the lower cover layer.

21. The method of claim 19, wherein when a distance between a lower surface of the ceramic body and the lower marking electrode is B2, 1 μm≦B2≦7 μm is satisfied.

22. A circuit board for mounting an electronic component comprising:
a printed circuit board having first and second electrode pads formed thereon; and
a multilayer ceramic capacitor installed on the printed circuit board,
wherein the multilayer ceramic capacitor includes:
a ceramic body including a plurality of dielectric layers laminated therein;
an active part including a plurality of first and second internal electrodes alternately exposed to both end surfaces of the ceramic body, having the dielectric layer interposed therebetween, and forming capacitance;
an upper cover layer formed on the active part and including an upper marking electrode therein; and
first and second external electrodes formed to cover the end surfaces of the ceramic body, and
when a thickness of the dielectric layer is d and a distance between a first internal electrode formed in the uppermost portion of the active part and the upper marking electrode is A1, 2d≦A1 is satisfied.
